(19) United States
(12) Patent Application Publication
(10) Pub. No.: US 2026/0239858 A1
(43) Pub. Date: Aug. 13, 2026

(54) DISPLAY DEVICE AND METHOD FOR MANUFACTURING THE SAME

(71) Applicant: Samsung Display Co., LTD., Yongin-si (KR)

(72) Inventor: Yoon Seok KA, Yongin-si (KR)

(21) Appl. No.: 19/304,041

(22) Filed: Aug. 19, 2025

(30) Foreign Application Priority Data
Feb. 10, 2025 (KR) 10-2025-0016646

(51) Int. Cl. H10K 59/80; G03F 7/00; G03F 7/027; G03F 7/16; H10K 59/12

(52) U.S. Cl. CPC H10K 59/873; G03F 7/0007; G03F 7/027; G03F 7/168; G03F 7/70425; H10K 59/1201

(57) ABSTRACT

A display device, an electronic device including the display device, and a method of manufacturing the display device are provided. The display device includes: a substrate; a plurality of light emitting elements on the substrate; and an encapsulation layer on the plurality of light emitting elements, wherein the encapsulation layer may include: a first inorganic encapsulation layer; a monomer layer on the first inorganic encapsulation layer, the monomer layer including a photoacid-generating monomer including an organic acid group represented by the following chemical formula 1; and a second inorganic encapsulation layer on the monomer layer

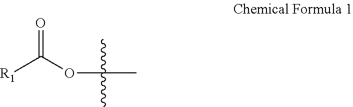

wherein R₁ is as described herein.

### CROSS-REFERENCE TO RELATED APPLICATION

This application claims priority from Korean Patent Application No. 10-2025-0016646 filed on Feb. 10, 2025 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a display device and a method for manufacturing the display device.

### 2. Description of the Related Art

As an information society develops, the demand for a display device for showing an image is increasing for various media. For example, the display device is applied to various electronic devices, such as smartphones, digital cameras, laptop computers, navigation devices, and smart televisions.

The display device may be a flat panel display device such as a liquid crystal display device, a field emission display device, or a light emitting display device. The light emitting display device may include an organic light emitting display device including an organic light emitting element, an inorganic light emitting display device including an inorganic light emitting element such as an inorganic semiconductor, and a micro or nano light emitting display device including a micro or nano light emitting element.

In order to improve the color reproducibility of the display device, development of a light emitting element using quantum dots as a light emitting material is in progress, and there is a demand for improving the light emitting efficiency and lifespan of the light emitting element using the quantum dots. Increased stability of display devices may maximize the versatility of the display device. To increase the stability of the display devices, an aging process may be performed.

### SUMMARY

Aspects of the present disclosure provide a display device having excellent light emitting efficiency by introducing a monomer layer including a photoacid-generating monomer including an organic acid group into an encapsulation layer.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of embodiments of the present disclosure, there may be provided a display device including: a substrate; a plurality of light emitting elements on the substrate; and an encapsulation layer on the plurality of light emitting elements, wherein the encapsulation layer may include: a first inorganic encapsulation layer; a monomer layer on the first inorganic encapsulation layer and including a photoacid-generating monomer including an organic acid group represented by the following chemical formula 1; and a second inorganic encapsulation layer on the monomer layer:

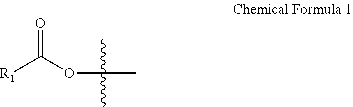

wherein in the chemical formula 1,
R₁ is H, a substituted or unsubstituted C₁₋₈ linear or branched alkyl group, a substituted or unsubstituted C₂₋₈ linear or branched alkenyl group, a substituted or unsubstituted C₃₋₈ cycloalkyl group, a substituted or unsubstituted C₃₋₈ heterocycloalkyl group, a substituted or unsubstituted C₆₋₈ aryl group, or a substituted or unsubstituted C₆₋₈ heteroaryl group.

When the monomer layer is exposed to light of a wavelength of 360 nm to 410 nanometer (nm), the photoacid-generating monomer may be cured to provide o a photoacid-generating polymer.

When the monomer layer is exposed to light of a wavelength of 255 nm or less, an organic acid derivative represented by the following chemical formula 2 may be separated from the photoacid-generating polymer:

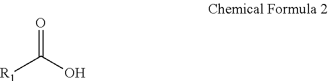

wherein in the chemical formula 2, R₁ is H, a substituted or unsubstituted C₁₋₈ linear or branched alkyl group, a substituted or unsubstituted C₂₋₈ linear or branched alkenyl group, a substituted or unsubstituted C₃₋₈ cycloalkyl group, a substituted or unsubstituted C₃₋₈ heterocycloalkyl group, a substituted or unsubstituted C₆₋₈ aryl group, or a substituted or unsubstituted C₆₋₈ heteroaryl group.

A volatile point of the organic acid derivative may be 70° C. or lower.

An acid dissociation constant (pKa) of the organic acid derivative may be from 1.0 to 5.5.

The plurality of light emitting elements may include: a first light emitting element that emits light in a first wavelength band and may be in a first light emitting area; a second light emitting element that emits light in a second wavelength band and may be in a second light emitting area; and a third light emitting element that emits light in a third wavelength band and may be in a third light emitting area.

The monomer layer may include: a first portion overlapping the first light emitting area in a thickness direction of the substrate; a second portion overlapping the second light emitting area in the thickness direction of the substrate; and a third portion overlapping the third light emitting area in the thickness direction of the substrate, wherein an amount of the organic acid derivative of the first portion, an amount of the organic acid derivative of the second portion, and an amount of the organic acid derivative of the third portion are different.

May further including an organic encapsulation layer between the monomer layer and the second inorganic encapsulation layer.

May further including a color filter layer on the encapsulation layer.

According to an aspect of embodiments of the present disclosure, there may be provided a method for manufacturing a display device, the method including: forming a plurality of light emitting elements on a substrate; and forming an encapsulation layer on the plurality of light emitting elements, wherein the forming of the encapsulation layer may include: forming a first inorganic encapsulation layer; forming a monomer layer including a photoacid-generating monomer may include an organic acid group represented by the chemical formula 1 on the first inorganic encapsulation layer; and forming a second inorganic encapsulation layer on the monomer layer.

The forming of the encapsulation layer may further include curing the photoacid-generating monomer into a photoacid-generating polymer by irradiating the monomer layer with light of a wavelength of 360 nm to 410 nm.

The forming of the encapsulation layer may further include separating an organic acid derivative represented by the chemical formula 2 from the photoacid-generating polymer by irradiating the monomer layer with light of a wavelength of 255 nm or less.

The forming of the plurality of light emitting elements may include: forming a first light emitting element that emits light in a first wavelength band in a first light emitting area; forming a second light emitting element that emits light in a second wavelength band in a second light emitting area; and forming a third light emitting element that emits light in a third wavelength band in a third light emitting area.

The monomer layer may include: a first portion overlapping the first light emitting area in a thickness direction of the substrate; a second portion overlapping the second light emitting area in the thickness direction of the substrate; and a third portion overlapping the third light emitting area in the thickness direction of the substrate.

The forming of the encapsulation layer may further include: irradiating the first portion with light of a wavelength of 255 nm or less at a first intensity using a mask; irradiating the second portion with light of a wavelength of 255 nm or less at a second intensity using a mask; and irradiating the third portion with light of a wavelength of 255 nm or less at a third intensity using a mask, and the first intensity, the second intensity, and the third intensity are different.

The forming of the encapsulation layer may further include: irradiating the first portion with light of a wavelength of 255 nm or less for a first time using a mask; irradiating the second portion with light of a wavelength of 255 nm or less for a second time using a mask; and irradiating the third portion with light of a wavelength of 255 nm or less for a third time using a mask, and the first time, the second time, and the third time are different.

An amount of the organic acid derivative of the first portion, an amount of the organic acid derivative of the second portion, and an amount of the organic acid derivative of the third portion are different.

The forming of the encapsulation layer may further include performing heat treatment at a temperature of 70° C. or lower.

The forming of the encapsulation layer may further include forming an organic encapsulation layer on the monomer layer.

According to an aspect of embodiments of the present disclosure, there may be provided an electronic device including: a display device providing an image; and a processor transmitting a video data signal to the display device, wherein the display device may include: a substrate; a plurality of light emitting elements on the substrate; and an encapsulation layer on the plurality of light emitting elements, wherein the encapsulation layer includes: a first inorganic encapsulation layer; a polymerized monomer layer on the first inorganic encapsulation layer, the monomer layer including a photoacid-generating monomer including an organic acid group represented by the chemical formula 1; and a second inorganic encapsulation layer on the monomer layer.

According to the display device according to embodiments, the amount of organic acid derivative generated may be easily adjusted by introducing the monomer layer including the photoacid-generating monomer including the organic acid group. By supplying an appropriate amount of the organic acid derivative, a passivation layer is formed on a metal oxide, thereby suppressing surface defects of the metal oxide.

Further, in the light emitting element, the charge balance may be improved, the leakage current may be reduced, and the extinction phenomenon may be improved.

The monomer layer of the present disclosure may improve the light emitting efficiency because it may adjust the amount of organic acid derivative generated for each area.

However, the effects of the embodiments are not restricted to the ones set forth herein. The above and other effects of the embodiments will become more apparent to one of daily skill in the art to which the embodiments pertain by referencing the claims.

### BRIEF DESCRIPTION OF THE DRAWINGS

FIG. 1 is a plan view illustrating a display device according to an exemplary embodiment.

FIG. 2 is a cross-sectional view taken along line A-A′ of FIG. 1.

FIG. 3 is a cross-section view illustrating a display panel according to an embodiment.

FIG. 4 is a flowchart illustrating a method for manufacturing a display device according to an exemplary embodiment.

FIG. 5 is a cross-sectional view illustrating the substrate and the plurality of light emitting elements in step S100 of FIG. 4.

FIG. 6 is a flowchart illustrating the step of forming the encapsulation layer in step S200 of FIG. 4.

FIG. 7 is a cross-sectional view illustrating the substrate, the plurality of light emitting elements, and the first inorganic encapsulation layer in step S210 of FIG. 6.

FIG. 8 is a cross-sectional view illustrating the substrate, the plurality of light emitting elements, the first inorganic encapsulation layer, and the monomer layer in step S220 of FIG. 6.

FIG. 9 is a view illustrating a step of forming a photoacid-generating polymer by curing a monomer layer with ultraviolet light in step S220 of FIG. 6.

FIG. 10 is a view illustrating a step of irradiating ultraviolet light to a first portion using a mask in step S220 of FIG. 6.

FIG. 11 is a view illustrating a step of irradiating ultraviolet light to a second portion using a mask in step S220 of FIG. 6.

FIG. 12 is a view illustrating a step of irradiating ultraviolet light to a third portion using a mask in step S220 of FIG. 6.

FIG. 13 is a cross-sectional view illustrating the substrate, the plurality of light emitting elements, the first inorganic encapsulation layer, the monomer layer, and the organic encapsulation layer.

FIG. 14 is a cross-sectional view illustrating the substrate, the plurality of light emitting elements, the first inorganic encapsulation layer, the monomer layer, the organic encapsulation layer, and the second inorganic encapsulation layer in step S230 of FIG. 6.

FIG. 15 is a cross-sectional view illustrating the substrate, the plurality of light emitting elements, the first inorganic encapsulation layer, the monomer layer, the organic encapsulation layer, the second inorganic encapsulation layer, and the color filter layer.

FIG. 16 is a block diagram of an electronic display device according to an embodiment.

FIG. 17 illustrates schematic diagrams of electronic devices according to various embodiments.

The above and other aspects and features of the present disclosure will become more apparent by describing in detail exemplary embodiments thereof with reference to the attached drawings, in which:

### DETAILED DESCRIPTION OF THE EMBODIMENTS

It is understood that the advantages and features of the main body and the method of utilizing the living body are described in detail below along with the attached technology. However, the present invention is not limited to other various forms of example resources, but only the present invention is fully included in the scope of the present invention and is provided to those who can use the vast technology in various technical fields of the present invention to make the category of the technology complete, the technology is defined by the scope.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, and the like may be used herein to describe various elements, these elements, should not be limited by these terms. These terms may be used to distinguish one element from another element. Thus, a first element discussed below may be termed a second element without departing from teachings of one or more embodiments. The description of an element as a “first” element is not limited to requiring or implying the presence of a second element or other elements. The terms “first”, “second”, and the like may also be used herein to differentiate different categories or sets of elements. For conciseness, the terms “first”, “second”, and the like may represent “first-category (or first-set)”, “second-category (or second-set)”, and the like, respectively.

The terminology used herein is for the purpose of describing particular embodiments and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, and/or components.

The term “substantially,” as used herein, means approximately or actually. The term “substantially equal” means approximately or actually equal. The term “substantially the same” means approximately or actually the same. The term “substantially identical” means approximately or actually identical. The term “substantially perpendicular” means approximately or actually perpendicular.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Embodiments are described herein with reference to cross section illustrations that are schematic illustrations of example embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C,” “at least one of A, B, and C”, and “at least one of A, B, or C”, may include any one of, or all possible combinations of the items enumerated together in a corresponding one of the phrases.

Features of various embodiments of the present disclosure may be combined partially or totally. As will be clearly appreciated by those skilled in the art, technically various interactions and operations are possible. Various embodiments can be practiced individually or in combination.

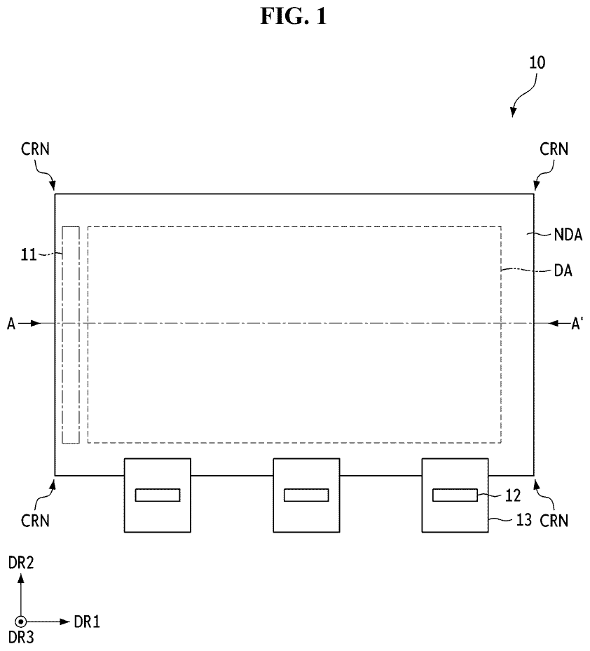

FIG. 1 is a plan view illustrating a display device according to an exemplary embodiment.

Referring to FIG. 1, a display device 10 according to an embodiment is a device that displays a moving image or a still image, and may be used as a display screen of each of various products such as a television, a laptop computer, a monitor, a billboard, and Internet of Things (IoT) as well as portable electronic devices such as a mobile phone, a smartphone, a tablet personal computer (PC), a smartwatch, a watch phone, a mobile communication terminal, an electronic organizer, an electronic book, a portable multimedia player (PMP), a navigation device, and an ultra mobile PC (UMPC).

The display device 10 may be a light emitting display device such as an organic light emitting display device using an organic light emitting diode, a quantum dot light emitting display device including a quantum dot light emitting layer, an inorganic light emitting display device including an inorganic semiconductor, and a micro light emitting display device using a micro or nano light emitting diode (micro or nano LED). Hereinafter, the description will be mainly made based on the display device 10 is a quantum dot light emitting display device. However, the display device is not limited thereto, and may be applied to an organic light emitting display device, an inorganic light emitting display device, or a micro or nano light emitting diode.

The display device 10 may be formed to be flat but is not limited thereto. For example, the display device 10 may include curved surface portions formed at left and right distal ends thereof and having a constant curvature or a variable curvature. In addition, the display device 10 may be flexibly formed to be curved, bent, folded, or rolled.

According to an embodiment, the display device 10 may be an organic light emitting display device.

As illustrated in FIG. 1, the display device 10 according to the embodiments may include one surface of a square. This is an example and not meant to be limiting, and the shape of the display device 10 is not limited to that illustrated in FIG. 1. That is, the display device 10 according to the embodiments may include one surface of a polygon or circle in addition to the square. Alternatively, at least a portion of the display device 10 may be deformed from an unfolded form to a bent, curved, folded, or rolled form.

One surface of the display device 10 may include a display area DA from which light for displaying an image is emitted, and a non-display area NDA surrounding the display area DA.

The display area DA may be disposed over most of one surface of the display device 10.

The non-display area NDA may be in the form of a frame from which no light for displaying an image is emitted and surrounding the display area DA. As an example, the non-display area NDA may be kept in a specific color, such as black.

One surface of the display device 10 may include corners CRN where sides in intersecting directions meet. As an example, when one surface of the display device 10 has a square shape, the one surface of the display device 10 may include four corners CRN.

The display device 10 may include drivers 11 and 12 that transmit signals, voltages, or power to light emitting pixel drivers in the display area DA.

A portion 11 of the drivers 11 and 12 that may be implemented with relatively simple circuits may be in the non-display area NDA.

Some other drivers 12 among the drivers 11 and 12 may be provided as an integrated circuit chip and may be mounted on a circuit board 13 electrically connected to pads in the non-display area NDA. Alternatively, some other drivers 12 may be mounted on the pads in the non-display area NDA.

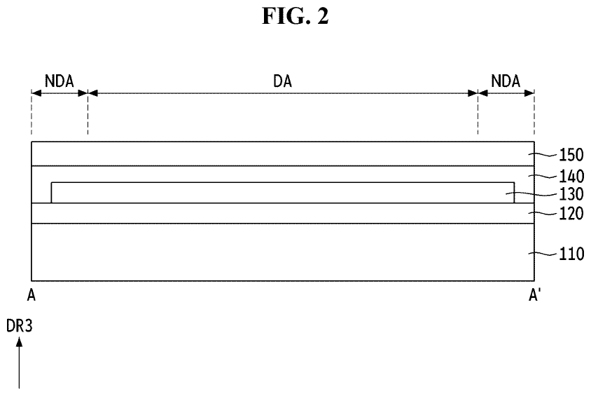

FIG. 2 is a cross-sectional view taken along line A-A′ of FIG. 1.

Referring to FIG. 2, the display device 10 according to an embodiment may include a display area DA from which light for displaying an image is emitted, and a non-display area NDA around the display area DA and from which no light is emitted.

According to an embodiment, the display device 10 may include a substrate 110 including a display area DA and a non-display area NDA, and a circuit layer 120, an element layer 130, an encapsulation layer 140, and a color filter layer 150 on the substrate 110.

The element layer 130 may be on the circuit layer 120.

That is, according to an embodiment, the display device 10 may include a substrate 110, a circuit layer 120 on the substrate 110, an element layer 130 on the circuit layer 120, an encapsulation layer 140 on the element layer 130, and a color filter layer 150 on the encapsulation layer 140.

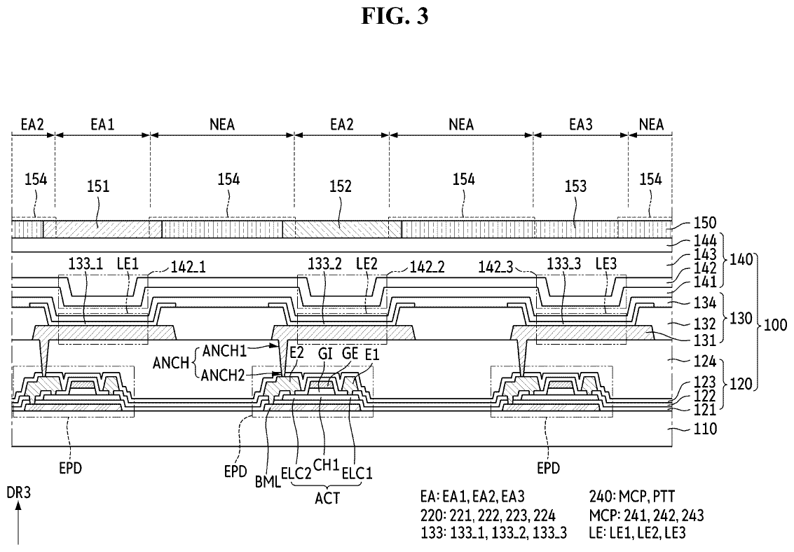

FIG. 3 is a cross-section view illustrating a display panel according to an embodiment.

Referring to FIG. 3, the display device 10 may include a substrate 110, a circuit layer 120 on the substrate 110, an element layer 130 including light emitting elements LE in light emitting areas EA on the circuit layer 120, an encapsulation layer 140 covering the element layer 130, and a color filter layer 150 on the encapsulation layer 140. Light emitted from the light emitting elements LE of the element layer 130 may pass through the color filter layer 150 and be emitted to the outside.

The substrate 110 may include a display area (DA in FIG. 1) and a non-display area (NDA in FIG. 1).

The display area DA may include light emitting areas (EA: EA1, EA2, and EA3 in FIG. 3) arranged in parallel to each other, and a non-light emitting area NEA between the light emitting areas (EA: EA1, EA2, and EA3 in FIG. 3).

The circuit layer 120 may include a buffer layer 121 on the substrate 110, a first interlayer insulating layer 122 on the buffer layer 121, a second interlayer insulating layer 123 on the first interlayer insulating layer 122, and a planarization layer 124 on the second interlayer insulating layer 123.

Each of the buffer layer 121, the first interlayer insulating layer 122, and the second interlayer insulating layer 123 may include an inorganic insulating material.

The planarization layer 124 may include an organic insulating material.

The circuit layer 120 may include light emitting pixel drivers EPD that transmit a driving current to the light emitting elements LE.

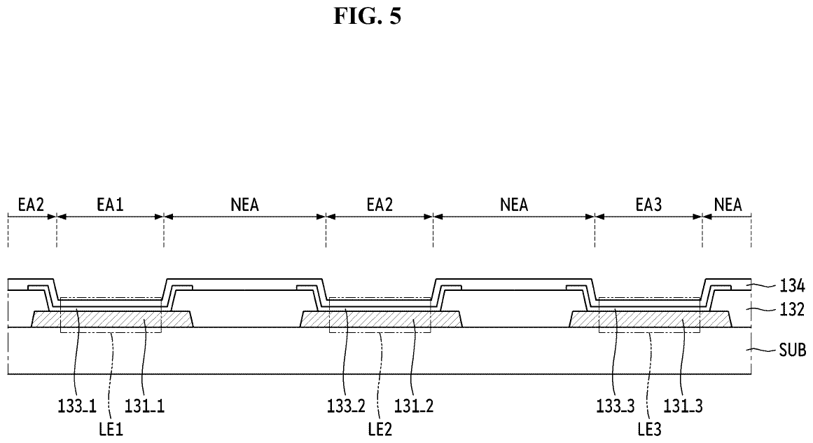

Each of the light emitting pixel drivers EPD may include two or more transistors (ST1, ST2, and ST3 in FIG. 5) and may be electrically connected to one or more lines (DL, VDL, VIL, GWL, and GIL in FIG. 5).

A first transistor ST1 of each of the light emitting pixel drivers EPD may include an active layer ACT on the buffer layer 121, a gate insulating layer GI covering a channel portion CH1 of the active layer ACT, a gate electrode GE on the gate insulating layer GI, and a first transistor electrode E1 and a second transistor electrode E2 on the first interlayer insulating layer 122 covering the active layer ACT and the gate electrode GE.

At least the channel portion CH1 of the active layer ACT may overlap a light blocking layer BML on the substrate 110.

The buffer layer 121 may cover the light blocking layer BML.

The active layer ACT may include a channel portion CH1, a first transistor electrode portion ELC1 connected to one side of the channel portion CH1, and a second transistor electrode portion ELC2 connected to the other side of the channel portion CH1.

The first transistor electrode E1 may be electrically connected to the first transistor electrode portion ELC1 of the active layer ACT1 through a hole penetrating through the first interlayer insulating layer 122.

The second transistor electrode E2 may be electrically connected to the second transistor electrode portion ELC2 of the active layer ACT1 through a hole penetrating through the first interlayer insulating layer 122.

The second transistor electrode E2 may be electrically connected to the light blocking layer BML through a hole penetrating through the first interlayer insulating layer 122 and the buffer layer 121.

An upper surface of the channel portion CH1 may face the gate electrode GE, and a back surface of the channel portion CH1 may face the light blocking layer BML electrically connected to the second transistor electrode E2.

Accordingly, depending on the same potential of the light blocking layer BML as the second transistor electrode E2, a portion of the active layer ACT adjacent to the light blocking layer BML may be activated relatively weakly compared to another portion thereof adjacent to the gate electrode GE.

The second interlayer insulating layer 123 may cover the first interlayer insulating layer 122, the first transistor electrode E1, and the second transistor electrode E2.

The planarization layer 124 may cover the second interlayer insulating layer 123 and include an organic insulating material.

The element layer 130 may be on the planarization layer 124 of the circuit layer 120.

The element layer 130 includes light emitting elements LE in light emitting areas EA.

Each of the light emitting elements LE may include a structure in which the light emitting layers 133 are between a first light emitting electrode 131 and a second light emitting electrode 134 opposing each other.

That is, the element layer 130 may include first light emitting electrodes 131 in the light emitting areas EA on the circuit layer 120, a pixel defining layer 132 in the non-light emitting area NEA on the circuit layer 120 and covering edges of the first light emitting electrodes 131, a light emitting layer 133 on the first light emitting electrodes 131, and a second light emitting electrode 134 on the light emitting layer 133.

The light emitting layers 133 may be each in the light emitting areas EA and spaced apart from each other. A first light emitting layer 133_1 in a first light emitting area EA1 may emit light in a first wavelength band. A second light emitting layer 1332 in a second light emitting area EA2 may emit light in a second wavelength band. A third light emitting layer 133_3 in a third light emitting area EA3 may emit light in a third wavelength band.

The first light emitting electrodes 131 may be electrically connected to the light emitting pixel drivers EPD through an anode connection hole ANCH.

That is, the first light emitting electrode 131 may be electrically connected to the second transistor electrode E2 of the first transistor ST1 of the light emitting pixel driver EPD through the anode connection hole ANCH.

The anode connection hole ANCH may penetrate through the planarization layer 124 and the second interlayer insulating layer 123.

The first light emitting electrode 131 is conductive. The first light emitting electrode 131 may include a metal alloy or a conductive compound. The first light emitting electrode 131 may be an anode. The first light emitting electrode 131 may be a pixel electrode.

In the light emitting element LE according to an embodiment, the first light emitting electrode 131 may be a reflective electrode. However, the embodiment is not limited thereto. For example, the first light emitting electrode 131 may be a transmissive electrode or a semi-transmissive electrode. When the first light emitting electrode 131 is a semi-transmissive electrode or a reflective electrode, the first light emitting electrode 131 may include Ag, Mg, Cu, Al, Pt, Pd, Au, Ni, Nd, Ir, Cr, Li, Ca, LiF/Ca, LiF/Al, Mo, Ti, or a compound or mixture thereof (e.g., a mixture of Ag and Mg). Alternatively, the first light emitting electrode 131 may have a multilayer structure including a reflective film or a semi-transparent film including the materials exemplified above and a transparent conductive film including indium tin oxide (ITO), indium zinc oxide (IZO), zinc oxide (ZnO), indium tin zinc oxide (ITZO), or the like. For example, the first light emitting electrode 131 may be a multilayer metal film and may have a structure in which metal films of ITO/Ag/ITO are stacked.

The pixel defining layer 132 may include an insulating material.

The light emitting layer 133 may include quantum dots.

The quantum dots refer to crystals of semiconductor compounds. The quantum dots may emit light of various emission wavelengths depending on the size of the crystal. The quantum dots may also emit light of various emission wavelengths by adjusting an element ratio in the quantum dot compound.

The first light emitting layer 1331 may include a quantum dot that emits light in a first wavelength band. The second light emitting layer 1332 may include a quantum dot that emits light in a second wavelength band. The third light emitting layer 133_3 may include a quantum dot that emits light in a third wavelength band.

A diameter of the quantum dot may be, for example, about 1 nm to 10 nm. The quantum dots may be synthesized by a wet chemical process, an organometallic chemical vapor deposition process, a molecular beam epitaxy process, or similar processes.

A core of the quantum dot may be selected from a group II-VI compound, a group III-V compound, a group III-VI compound, a group I-III-VI compound, a group IV-VI compound, a group IV element, a group IV compound, and a combination thereof.

The group II-VI compound may be selected from the group consisting of a binary compound selected from the group consisting of CdSe, CdTe, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof. The II-VI group semiconductor compound may further include a group I metal and/or a group IV element. The group I-II-VI compound may be selected from CuSnS or CuZnS, and the group II-IV-VI compound may be ZnSnS, or the like. The group I-II-IV-VI compound may be selected from a quaternary compound selected from the group consisting of Cu₂ZnSnS₂, Cu₂ZnSnS₄, Cu₂ZnSnSe₄, Ag₂ZnSnS₂, and mixtures thereof.

The group III-VI compound may include a binary compound such as In₂S₃ or In₂Se₃, a ternary compound such as InGaS₃ or InGaSe₃, or any combination thereof.

The group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO₂, and mixtures thereof, or a quaternary compound such as AgInGaS₂ or CuInGaS₂.

The group III-V compound may be selected from the group consisting of a binary compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. The group III-V compound may further include group II metals. For example, InZnP and the like may be selected as the group III-II-V compound.

The group IV-VI compound may be selected from the group consisting of a binary compound selected from the group consisting of SnS, SnSe, SnTe, PbS, PbSe, PbTe, and mixtures thereof; a ternary compound selected from the group consisting of SnSeS, SnSeTe, SnSTe, PbSeS, PbSeTe, PbSTe, SnPbS, SnPbSe, SnPbTe, and mixtures thereof; and a quaternary compound selected from the group consisting of SnPbSSe, SnPbSeTe, SnPbSTe, and mixtures thereof.

Examples of II-IV-V group semiconductor compounds may be ternary compounds selected from the group consisting of ZnSnP, ZnSnP₂, ZnSnAs2, ZnGeP₂, ZnGeAs₂, CdSnP₂, CdGeP₂, and mixtures thereof.

A group IV element may be selected from the group consisting of Si, Ge, and mixtures thereof. A group IV compound may be a binary compound selected from the group consisting of SiC, SiGe, and mixtures thereof.

Each element included in a multi-element compound, such as a binary compound, a ternary compound, or a quaternary compound, may be present within a particle at a uniform or non-uniform concentration. That is, the chemical formula indicating the quantum dot means the type of element included in the quantum dot compound, and the element ratio within the compound may be different. For example, AgInGaS₂ may mean AgInₓGa₁₋ₓS₂ (where x is a real number between 0 and 1).

In this case, the binary compound, the ternary compound, or the quaternary compound may be present in a particle at a uniform concentration or may be present in the same particle in a state of partially different concentration distributions. In addition, the quantum dot may have a core/shell structure in which one quantum dot surrounds another quantum dot. The core/shell structure may have a concentration gradient in which a concentration of elements present in the shell decreases toward the core.

In some embodiments, the quantum dot may have a core-shell structure including a core including the above-described nanocrystals and a shell surrounding the core. The shell of the quantum dot may serve as a protective layer for maintaining semiconductor properties by preventing chemical modification of the core and/or a charging layer for imparting electrophoretic properties to the quantum dot. The shell may be a single layer or multiple layers. Examples of the shell of the quantum dot may include a metal or non-metal oxide, a semiconductor compound, or a combination thereof.

Examples of the metal or non-metal oxide may include, but are not limited to, a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO or a ternary compound such as MgAl₂O₄, CoFe₂O₄, NiFe₂O₄, or CoMn₂O₄, or combinations thereof.

In addition, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and AlSb, but the present disclosure is not limited thereto.

The quantum dot may have a full width of half maximum (FWHM) of an emission wavelength spectrum of about 45 nm or less, preferably about 40 nm or less, more preferably about 30 nm or less, and may improve color purity or color reproducibility within such a range. In addition, since light emitted through the quantum dot is emitted in all directions, a wide viewing angle may be improved.

In addition, the form of the quantum dot is one commonly used in the field and is not particularly limited, but more specifically, the quantum dot in the form of nanoparticles, nanotubes, nanowires, nanofibers, nanoplatelets, or the like, which are spherical, pyramidal, multi-arm, or cubic, may be used.

Since an energy band gap of the quantum dot may be adjusted by adjusting the size of the quantum dot or the element ratio within the quantum dot compound, light in various wavelength bands may be obtained from the quantum dot emitting layer. Therefore, by using the quantum dots as described above (using the quantum dots of different sizes or having different element ratios within the quantum dot compound), a light emitting element that emits light in various wavelength band may be implemented.

The second light emitting electrode 134 may be in the display area DA including the light emitting areas EA1, EA2, and EA3 (EA in FIG. 3) and the non-light emitting area NEA.

The second light emitting electrode 134 may be a common electrode or a cathode. The second light emitting electrode 134 may be a transmissive electrode, a semi-transmissive electrode, or a reflective electrode. When the second light emitting electrode 134 is a transmissive electrode, the second light emitting electrode 134 may include a transparent metal oxide, for example, indium tin oxide (ITO), indium zinc oxide (IZO), zinc oxide (ZnO), indium tin zinc oxide (ITZO), or the like.

When the second light emitting electrode 134 is a semi-transmissive electrode or a reflective electrode, the second light emitting electrode 134 may include Ag, Mg, Cu, Al, Pt, Pd, Au, Ni, Nd, Ir, Cr, Li, Ca, LiF/Ca, LiF/Al, Mo, Ti, Yb, or a compound (e.g., AgYb, AgMg and MgAg compound depending on the content) or a mixture (e.g., a mixture of Ag and Mg). Alternatively, the second light emitting electrode 134 may have a multi-layer structure including a reflective film or a semi-transparent film including the materials exemplified above and a transparent conductive film including indium tin oxide (ITO), indium zinc oxide (IZO), zinc oxide (ZnO), indium tin zinc oxide (ITZO), or the like.

The light emitting element LE may further include a hole transporting area (not illustrated) between the first light emitting electrode 131 and the light emitting layer 133. The hole transporting area may further include a hole injection layer and/or a hole transporting layer.

The light emitting element LE may further include an electron transporting area (not illustrated) between the light emitting layer 133 and the second light emitting electrode 134. The electron transporting area may further include an electron injection layer and/or an electron transporting layer.

The light emitting element LE may further include a capping layer CPL (not illustrated) on the second light emitting electrode 134. The capping layer CPL may include a multilayer or a single layer.

In an embodiment, the capping layer CPL may be an organic or inorganic layer. For example, when the capping layer CPL includes an inorganic material, the inorganic material may include an alkali metal compound such as LiF, an alkaline earth metal compound such as MgF₂, SiON, SiN_{X}, SiOy, or the like.

The encapsulation layer 140 may include a first inorganic encapsulation layer 141 on the element layer 130 and including an inorganic material, a monomer layer 142 on the first inorganic encapsulation layer 141 and including a photoacid-generating monomer including an organic acid group represented by the following chemical formula 1, and a second inorganic encapsulation layer 144 on the monomer layer 142 and including an inorganic material.

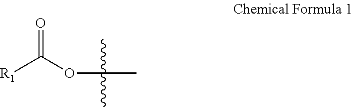

In the chemical formula 1, R₁ is H, a linear or branched alkyl group of C₁₋₈ which may be substituted, a linear or branched alkenyl group of C₂₋₈ which may be substituted, a cycloalkyl group of C₃₋₈ which may be substituted, a heterocycloalkyl group of C₃₋₈ which may be substituted, an aryl group of C₆₋₈ which may be substituted, or a heteroaryl group of C₆₋₈ which may be substituted.

The encapsulation layer 140 may further include an organic encapsulation layer 143 between the monomer layer 142 and the second inorganic encapsulation layer 144 and including an organic material.

The encapsulation layer 140 may reduce defects in the circuit layer 120 or the element layer 130 due to foreign substances, and may prevent oxygen or moisture from permeating into the circuit layer 120 or the element layer 130.

The encapsulation layer 140 may be on the second light emitting electrode 134. In addition, when the light emitting element LE according to an embodiment includes the capping layer CPL, the encapsulation layer 140 may be on the capping layer CPL.

The encapsulation layer 140 may include a plurality of stacked layers. The encapsulation layer 140 according to an embodiment may include at least one organic layer (hereinafter, an organic encapsulation layer) and at least one inorganic layer (hereinafter, an inorganic encapsulation layer). In addition, the encapsulation layer 140 according to an embodiment may include the monomer layer 142.

The first inorganic encapsulation layer 141 may be on the second light emitting electrode 134. When the light emitting element LE further includes the capping layer CPL, the encapsulation layer 141 may be on the capping layer CPL.

The first inorganic encapsulation layer 141 may function to protect the light emitting element LE from moisture and oxygen. The first inorganic encapsulation layer 141 may have a high film density by including an inorganic material and may have a strong bond with a functional layer under the first inorganic encapsulation layer 141. Accordingly, it is possible to prevent moisture or oxygen from permeating into an interface between the first inorganic encapsulation layer 141 and the functional layer under the first inorganic encapsulation layer 141, for example, the second light emitting electrode 134 or the capping layer CPL. In addition, the peeling of the first inorganic encapsulation layer 141 may be prevented. The first inorganic encapsulation layer 141 may include at least one of silicon nitride, silicon oxynitride, silicon oxide, titanium oxide, and aluminum oxide.

The monomer layer 142 may be on the first inorganic encapsulation layer 141. The monomer layer 142 may include a photoacid-generating monomer including an organic acid group represented by chemical formula 1.

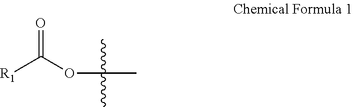

In the chemical formula 1, R₁ is H, a substituted or unsubstituted C₁₋₈ linear or branched alkyl group, a substituted or unsubstituted C₂₋₈ linear or branched alkenyl group, a substituted or unsubstituted C₃₋₈ cycloalkyl group, a substituted or unsubstituted C₃₋₈ heterocycloalkyl group, a substituted or unsubstituted C₆₋₈ aryl group, or a substituted or unsubstituted C₆₋₈ heteroaryl group.

The photoacid-generating monomer may be cured into a photoacid-generating polymer when exposed to a wavelength of 360 nm to 410 nm. When the photoacid-generating polymer is exposed to a wavelength of 255 nm or less, an organic acid derivative represented by the following chemical formula 2 may be separated from the photoacid-generating polymer.

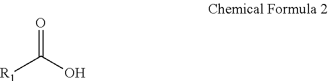

In the chemical formula 2, R₁ is H, a substituted or unsubstituted C₁₋₈ linear or branched alkyl group, a substituted or unsubstituted C₂₋₈ linear or branched alkenyl group, a substituted or unsubstituted C₃₋₈ cycloalkyl group, a substituted or unsubstituted C₃₋₈ heterocycloalkyl group, a substituted or unsubstituted C₆₋₈ aryl group, or a substituted or unsubstituted C₆₋₈ heteroaryl group.

The photoacid-generating monomer may be a polymerizable photoacid-generating monomer including an organic acid group represented by chemical formula 1. The photoacid-generating monomer may include a methacrylate group, an acrylate group, or a combination thereof. In an embodiment, the photoacid-generating monomer may include an acrylate group. The photoacid-generating monomer may be a monomer represented by the following chemical formulas 3, 4, and 5.

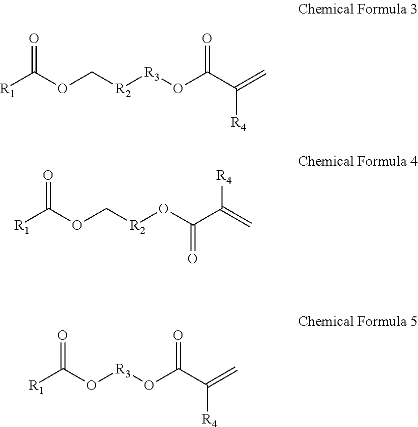

In the chemical formulas 3, 4, and 5, R₁ is H, a substituted or unsubstituted C₁₋₈ linear or branched alkyl group, a substituted or unsubstituted C₂₋₈ linear or branched alkenyl group, a substituted or unsubstituted C₃₋₈ cycloalkyl group, a substituted or unsubstituted C₃₋₈ heterocycloalkyl group, a substituted or unsubstituted C₆₋₈ aryl group, or a substituted or unsubstituted C₆₋₈ heteroaryl group, R₂ and R₃ are each independently a substituted or unsubstituted C₁₋₂₀ linear or branched alkyl group, a substituted or unsubstituted C₂₋₂₀ linear or branched alkenyl group, a substituted or unsubstituted C₃₋₂₀ cycloalkyl group, a substituted or unsubstituted C₃₋₂₀ heterocycloalkyl group, a substituted or unsubstituted C₆₋₂₀ aryl group, or a substituted or unsubstituted C₆₋₂₀ heteroaryl group, and R₄ is H, a substituted or unsubstituted C₁₋₈ linear or branched alkyl group or a substituted or unsubstituted linear or branched C₂₋₈ alkenyl group.

The photoacid-generating monomer may include a compound represented by the following chemical formula 6 or 7.

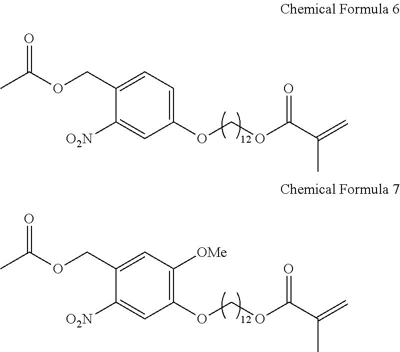

The photoacid-generating polymer may be a polymer in which acrylate groups of the photoacid-generating monomers are linked to each other. When two or more different photoacid-generating monomers are used, the photoacid-generating polymer may be a copolymer. The photoacid-generating polymer may form a rigid film. When the monomer layer is exposed to light of a wavelength of 360 nm to 410 nm, only the photoacid-generating polymer may be formed, and the organic acid derivative may not be separated.

The organic acid derivative may include an organic acid derivative represented by any one of the following A1 to A12.

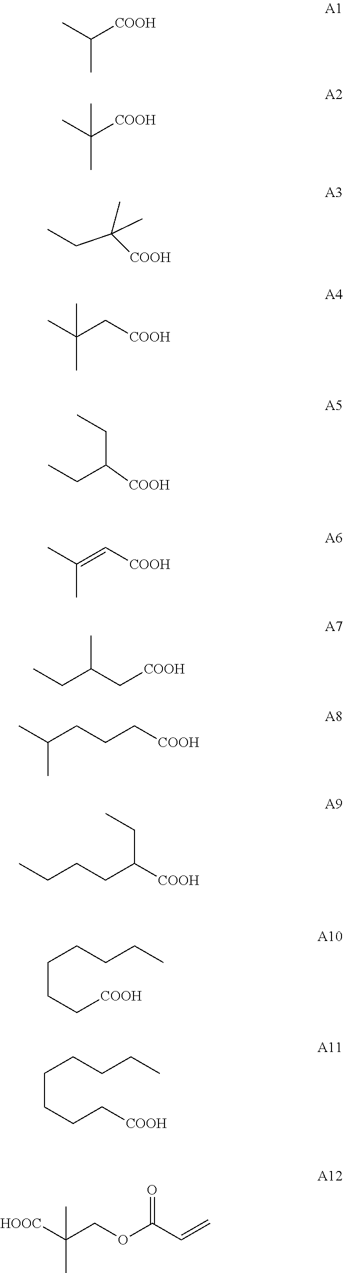

The monomer layer may include a first portion 142_1 overlapping the first light emitting area EA1 in a thickness direction of the substrate 110; a second portion 142_2 overlapping the second light emitting area EA2 in the thickness direction of the substrate 110; and a third portion 142_3 overlapping the third light emitting area EA3 in the thickness direction of the substrate 110.

The amount of the organic acid derivative of the first portion 142_1, the amount of the organic acid derivative of the second portion 1422, and the amount of the organic acid derivative of the third portion 142_3 may be different.

The electron transporting area may include a metal oxide. Since the metal oxide has oxygen vacancy defects, hole leakage may occur, which may reduce the durability of the display device. The present disclosure may easily adjust the amount of organic acid derivatives generated by introducing the monomer layer including the photoacid-generating monomer including the organic acid group. By supplying an appropriate amount of an organic acid derivative, a passivation layer is formed on the metal oxide, thereby suppressing surface defects of the metal oxide. In addition, in the light emitting element LE, a charge balance may be improved, a leakage current may be reduced, and an extinction phenomenon may be improved.

When the organic acid derivative is excessively supplied, damage to the light emitting element LE may increase during an aging process, which may result in a deterioration in the characteristics of the light emitting element LE. The photoacid-generating monomer of the present disclosure may supply an appropriate amount of an organic acid derivative by easily adjusting curing and separation of the organic acid derivative for each wavelength.

The quantum dot of the first light emitting layer 133_1, the quantum dot of the second light emitting layer 1332, and the quantum dot of the third light emitting layer 133_3 may each require different amounts of acid during aging. The monomer layer of the present disclosure may adjust the amount of organic acid derivative for each area. Specifically, when irradiating light of 255 nm wavelength to the first portion 142_1, the second portion 1422, and the third portion 142_3 of the monomer layer cured with the photoacid-generating polymer, the amount of separated organic acid derivative may be adjusted by adjusting the light intensity and/or irradiation time, respectively. The monomer layer of the present disclosure may improve the light emitting efficiency because it may adjust the amount of organic acid derivative generated for each area.

The amount of organic acid derivative may be adjusted depending on the thickness of the monomer layer. The thicker the monomer layer, the greater the amount of organic acid derivative that may be separated.

A volatile point, i.e., evaporation temperature, of the organic acid derivative may be 70° C. or lower.

When the monomer layer is exposed to light of a wavelength of 255 nm or less, the organic acid derivative separated from the photoacid-generating polymer remains inside the photoacid-generating polymer film. When the temperature of the photoacid-generating polymer film is heated, for example at or above the volatile point (evaporation temperature) of the organic acid derivative, the organic acid derivative may be vaporized, separated from the photoacid-generating polymer film, and diffused into the light emitting element LE. The organic acid derivative diffused into the light emitting element LE may improve aging performance of the light emitting element LE, thereby reducing quenching and improving the light emitting efficiency and lifespan of the light emitting element LE.

Since the volatile point of the organic acid derivative of the present disclosure is 70° C. or lower, a low-temperature process may be possible.

An acid dissociation constant (pKa) of the organic acid derivative may be from 1.0 to 5.5. When the acid dissociation constant of the organic acid derivative satisfies the above-mentioned range, the effect of improving the light emitting efficiency of the light emitting element LE may be increased.

The organic encapsulation layer 143 may be on the monomer layer 142. The organic encapsulation layer 143 may function to protect the display device 10 from foreign substances such as dust particles. The organic encapsulation layer 143 may have a flat upper surface. The organic encapsulation layer 143 may reduce a step difference of the monomer layer 142. The organic encapsulation layer 143 is provided to reduce a step difference of an upper surface of the monomer layer 142 so that a functional layer to be thereon may be uniformly disposed. In an embodiment, a thickness of the organic encapsulation layer 143 may be greater than a thickness of the monomer layer 142. In addition, the thickness of the organic encapsulation layer 143 may be greater than the thicknesses of the first inorganic encapsulation layer 141 and the second inorganic encapsulation layer 144. The organic encapsulation layer 143 may include a polymer.

The second inorganic encapsulation layer 144 may be on the organic encapsulation layer 143. The second inorganic encapsulation layer 144 may include an inorganic material. The second inorganic encapsulation layer 144 may protect the display device 10 from moisture and oxygen. The second inorganic encapsulation layer 144 may have a high bonding strength with the organic encapsulation layer 143, and thus may prevent moisture and oxygen from permeating into an interface between the second inorganic encapsulation layer 144 and the organic encapsulation layer 143.

Although not illustrated, the encapsulation layer 140 may further include an additional organic encapsulation layer and an additional inorganic encapsulation layer on the second inorganic encapsulation layer 144. The encapsulation layer 140 may further include n number of additional organic encapsulation layers (where n is a natural number greater than or equal to 1) and n additional inorganic encapsulation layers. The n additional organic encapsulation layers and the n additional inorganic encapsulation layers may be disposed alternately with each other. The n additional organic encapsulation layers may have, on average, a greater thickness than the n additional inorganic encapsulation layers, but embodiments are not limited thereto. With respect to the materials of the additional organic encapsulation layer and the additional inorganic encapsulation layer, the same contents as those described for the organic encapsulation layer 143, the first inorganic encapsulation layer 141, and the second inorganic encapsulation layer 144 may be applied.

The color filter layer 150 may be on the encapsulation layer 140. The color filter layer 150 may selectively transmit light of each of the light emitting areas EA emitted from the light emitting element LE in each of the light emitting areas EA.

The color filter layer 150 may include a first filter portion 151 in the first light emitting area EA1 and transmitting light in a first wavelength band, a second filter portion 152 in the second light emitting area EA2 and transmitting light in a second wavelength band, a third filter portion 153 in the third light emitting area EA3 and transmitting light in a third wavelength band, and a light blocking portion 154 in the non-light emitting area NEA and the non-display area (NDA in FIG. 1) and blocking light.

Each of the first filter portion 151, the second filter portion 152, and the third filter portion 153 may include a colorant such as a dye or pigment. The colorant may be a material that absorbs light in wavelength bands other than a predetermined wavelength band.

That is, the first filter portion 151 may include a colorant that absorbs light in wavelength bands other than the first wavelength band among the light emitting from the light emitting element LE, thereby transmitting the light in the first wavelength band.

The second filter portion 152 may include a colorant that absorbs light in wavelength bands other than the second wavelength band among the light emitting from the light emitting element LE, thereby transmitting the light in the second wavelength band.

The third filter portion 153 may include a colorant that absorbs light in wavelength bands other than the third wavelength band among the light emitting from the light emitting element LE, thereby transmitting the light in the third wavelength band.

The light blocking portion 154 may include a structure in which two or more filter portions among the first filter portion 151, the second filter portion 152, and the third filter portion 153 are stacked.

Alternatively, the light blocking portion 154 may also include a material that absorbs light, such as a black matrix material.

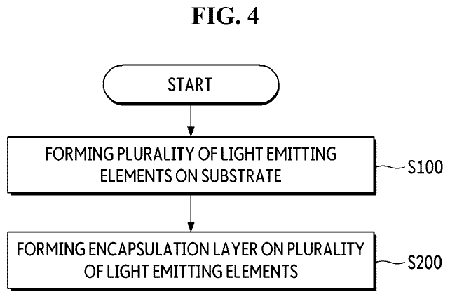

FIG. 4 is a flowchart illustrating a method for manufacturing a display device according to an exemplary embodiment.

First, a plurality of light emitting elements LE may be formed on a substrate SUB (S100). The substrate SUB may use the materials exemplified above, and the process method used to form the light emitting element LE is not limited.

FIG. 5 is a cross-sectional view illustrating the substrate and the plurality of light emitting elements in step S100 of FIG. 4.

The step of forming the plurality of light emitting elements may include a step of forming a first light emitting element LE1 that emits light in a first wavelength band in a first light emitting area EA1; a step of forming a second light emitting element LE2 that emits light in a second wavelength band in a second light emitting area EA2; and a step of forming a third light emitting element LE3 that emits light in a third wavelength band in a third light emitting area EA3.

Referring to FIG. 5, a first light emitting electrode 131_1 and a first light emitting layer 1331 may be formed in the first light emitting area EA1, a first light emitting electrode 131_2 and a second light emitting layer 133_1 may be formed in the second light emitting area EA2, and a first light emitting electrode 131_3 and a third light emitting layer 133_3 may be formed in the third light emitting area EA3. A pixel defining film 132 may be formed in the non-light emitting area NEA to partition the light emitting area EA. The second light emitting electrode 134 may be formed as a common layer covering the first light emitting electrode 131, the light emitting layer 133, and the pixel defining film 132.

Next, an encapsulation may be formed on the plurality of light emitting elements (S200).

The encapsulation layer 140 may be formed using the materials exemplified above, and the process method used to form the encapsulation layer 140 is not limited.

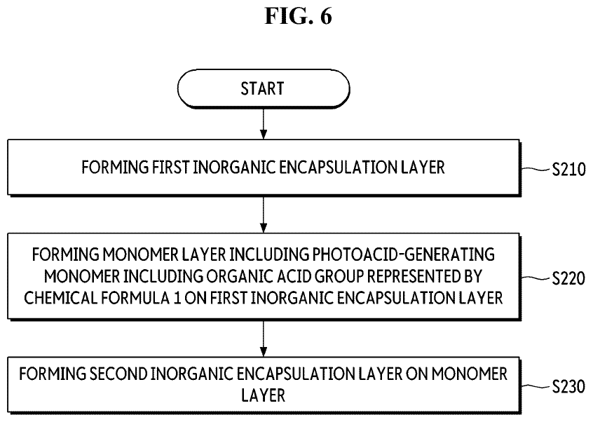

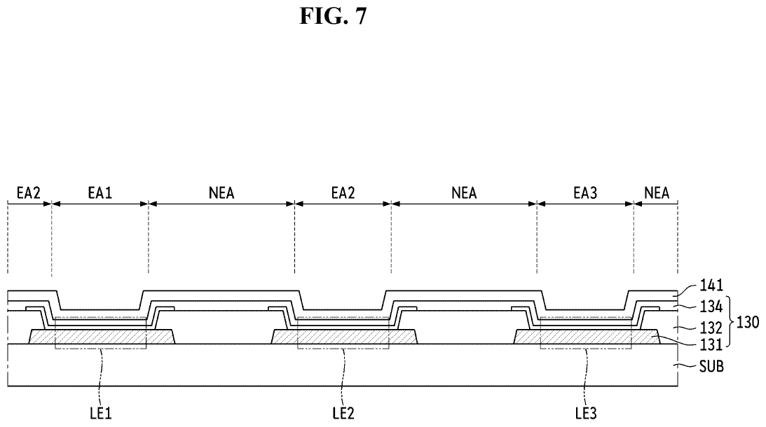

FIG. 6 is a flowchart illustrating the step of forming the encapsulation layer in step S200 of FIG. 4. FIG. 7 is a cross-sectional view illustrating the substrate, the plurality of light emitting elements, and the first inorganic encapsulation layer in step S210 of FIG. 6.

The first inorganic encapsulation layer 141 may be formed using the materials exemplified above, and the process method used to form the first inorganic encapsulation layer is not limited.

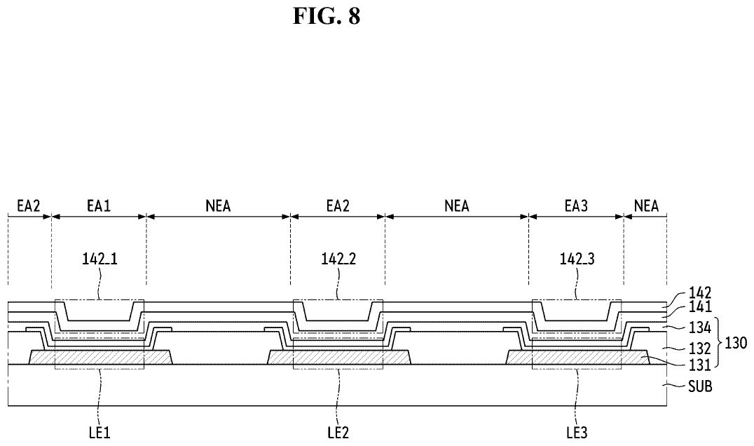

FIG. 8 is a cross-sectional view illustrating the substrate, the plurality of light emitting elements, the first inorganic encapsulation layer, and the monomer layer in step S220 of FIG. 6.

The monomer layer 142 may be formed using the materials exemplified above, and the process method used to form the monomer layer 142 is not limited.

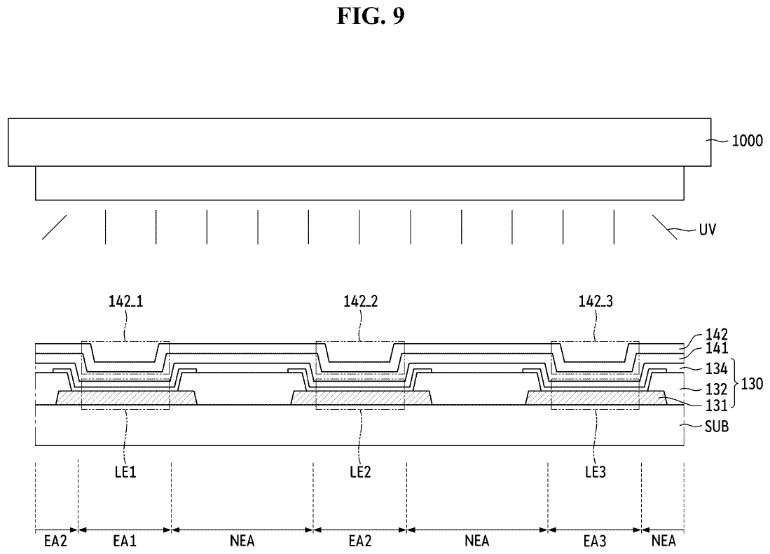

FIG. 9 is a view illustrating a step of forming a photoacid-generating polymer by curing a monomer layer with ultraviolet light in step S220 of FIG. 6.

Referring to FIG. 9, by irradiating ultraviolet (UV) light having a wavelength of 360 nm to 410 nm through an ultraviolet lamp 1000 onto the monomer layer 142 formed on the substrate SUB, the photoacid-generating monomer may be cured into a photoacid-generating polymer.

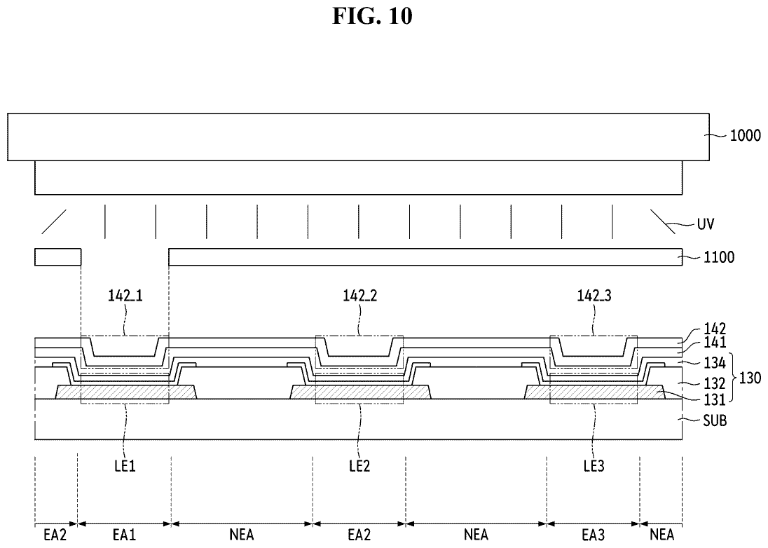

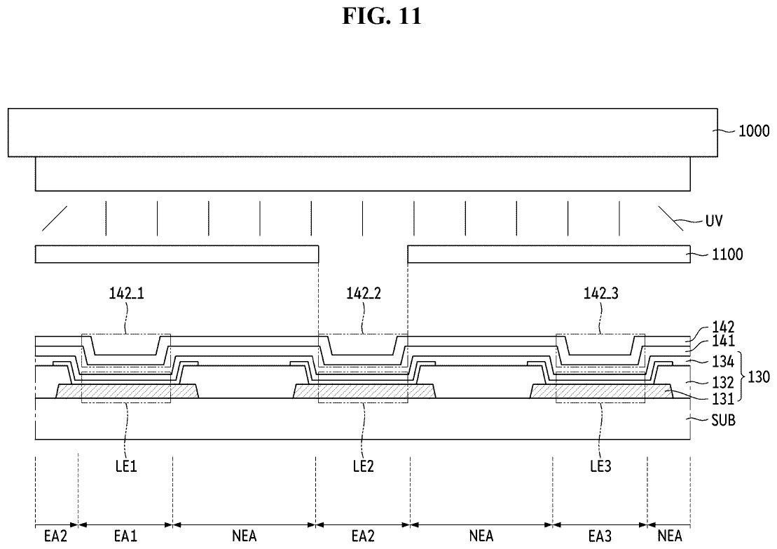

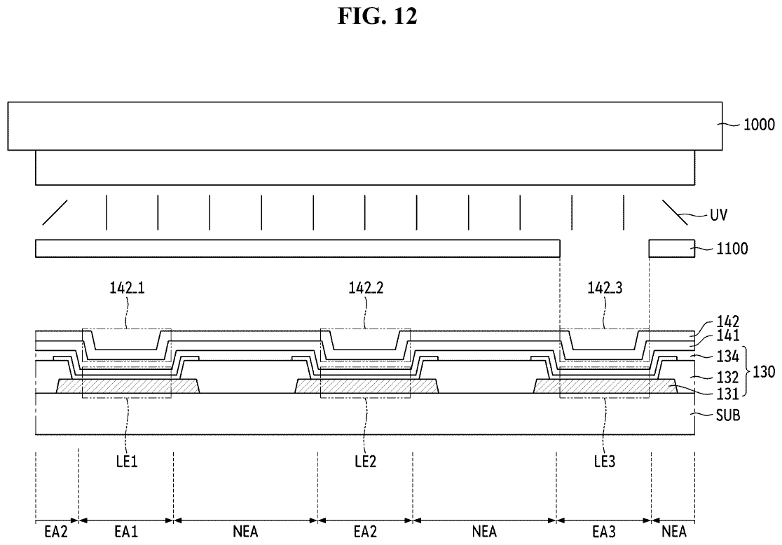

FIG. 10 is a view illustrating a step of irradiating ultraviolet light to a first portion using a mask in step S220 of FIG. 6. FIG. 11 is a view illustrating a step of irradiating ultraviolet light to a second portion using a mask in step S220 of FIG. 6. FIG. 12 is a view illustrating a step of irradiating ultraviolet light to a third portion using a mask in step S220 of FIG. 6.

Referring to FIGS. 10 to 12, ultraviolet light of 255 nm or less may be irradiated to each of the first portion 142_1, the second portion 1422, and the third portion 142_3 using a mask 1100. In this case, the first portion 1421 may be irradiated with light of a first intensity, the second portion 142_2 may be irradiated with light of a second intensity, and the third portion 1423 may be irradiated with light of a third intensity. The first to third intensities may be different.

For example, the intensity of light may be greater in the first intensity, the second intensity, and the third intensity, in that order. In this case, the amount of organic acid derivative separated from the third portion 142_3 irradiated with the light of the third intensity may be the largest.

In addition, the first portion 1421 may be irradiated with light for a first time, the second portion 1422 may be irradiated with light for a second time, and the third portion 142_3 may be irradiated with light for a third time. The first to third times may be different.

For example, the time may be longer in the order of the first time, the second time, and the third time. In this case, the amount of organic acid derivative separated from the third portion 142_3 irradiated with the light for the longest time may be the largest.

The intensity and time of light irradiation may be adjusted depending on the amount of organic acid derivative required in each of the first portion 142_1, the second portion 1422, and the third portion 142_3.

The step of forming the encapsulation layer may further include a step of performing heat treatment at a temperature of 70° C. or lower.

By performing heat treatment at a temperature of 70° C. or lower, which is the volatile point of the organic acid derivative, the organic acid derivative remaining inside the cured photoacid-generating polymer film may be vaporized and diffused into the light emitting element LE. Since the process is performed at low temperatures, the light emitting element LE may not be damaged by heat.

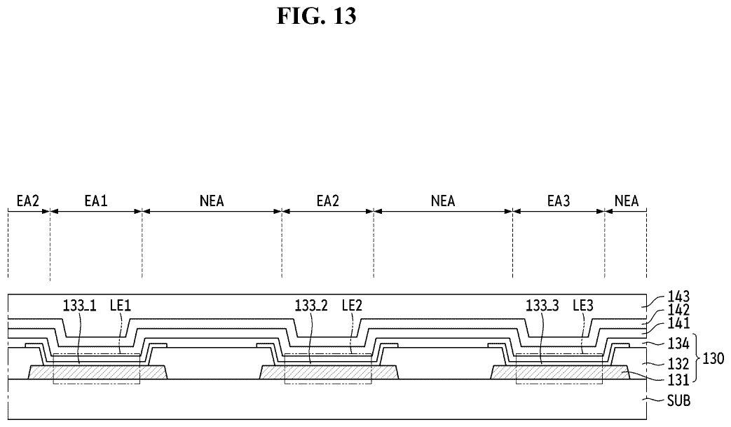

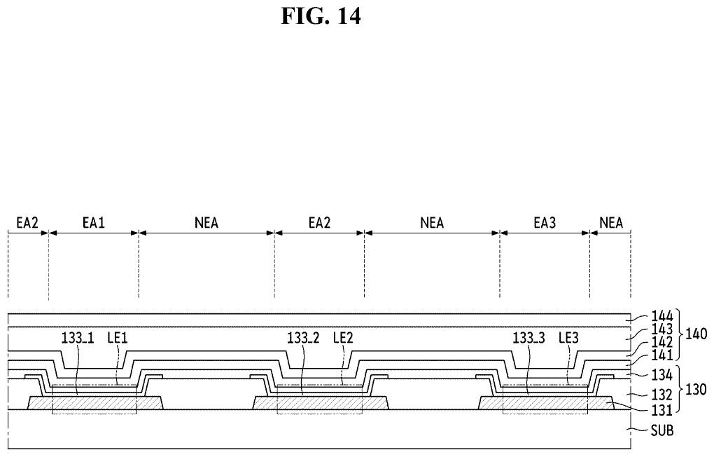

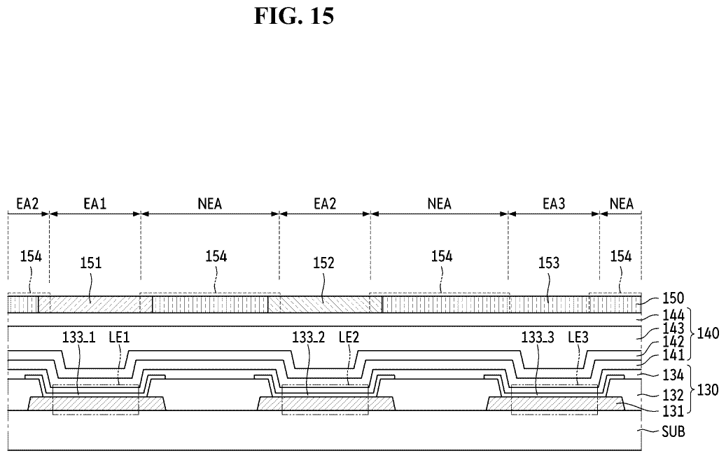

FIG. 13 is a cross-sectional view illustrating the substrate, the plurality of light emitting elements, the first inorganic encapsulation layer, the monomer layer, and the organic encapsulation layer. FIG. 14 is a cross-sectional view illustrating the substrate, the plurality of light emitting elements, the first inorganic encapsulation layer, the monomer, the organic encapsulation layer, and the second inorganic encapsulation layer in step S230 of FIG. 6. FIG. 15 is a cross-sectional view illustrating the substrate, the plurality of light emitting elements, the first inorganic encapsulation layer, the monomer, the organic encapsulation layer, the second inorganic encapsulation layer, and the color filter layer.

The organic encapsulation layer 143 may be formed using the materials exemplified above, and the process method used to form the organic encapsulation layer 143 is not limited thereto. The second inorganic encapsulation layer 144 may be formed using the materials exemplified above, and the process method used to form the second inorganic encapsulation layer 144 is not limited thereto. The color filter layer 150 may be formed using the materials exemplified above, and the process method used to form the color filter layer 150 is not limited thereto.

The display device according to the embodiment may be applied to, i.e., used in, various electronic devices.

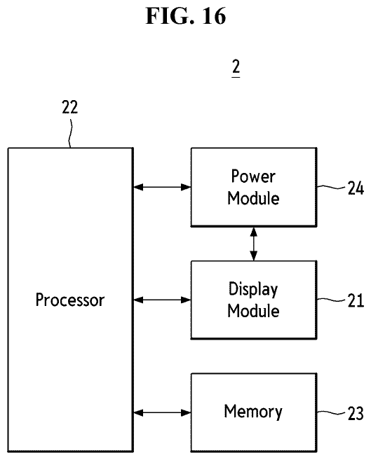

FIG. 16 is a block diagram of an electronic display device according to an embodiment. Referring to FIG. 16, an electronic device 2 according to an embodiment may include a display module 21, a processor 22, a memory 23, and a power module 24.

The processor 22 may include at least one of a central processing unit (CPU), an application processor (AP), a graphic processing unit (GPU), a communication processor (CP), an image signal processor (ISP), and a controller.

Data information necessary for an operation of the processor 22 or the display module 21 may be stored in the memory 23. When the processor 22 executes an application stored in the memory 23, image data signals and/or input control signals may be transmitted to the display module 21, and the display module 21 may process the provided signals and output image information through a display screen.

The power module 24 may include a power supply module, such as a power adapter or a battery device, and a power conversion module that converts power supplied by the power supply module to generate power required for an operation of the electronic device 2.

At least one of the components of the electronic device 2 described above may be included in the display device 10 according to the above-described embodiments. In addition, some of the individual modules functionally included within one module may be included within the display device 10, while others may be provided separately from the display device 10. For example, the display device 10 includes the display module 21, and the processor 22, the memory 23, and the power module 24 may be provided in the form of other devices within the electronic device 2 other than the display device 10.

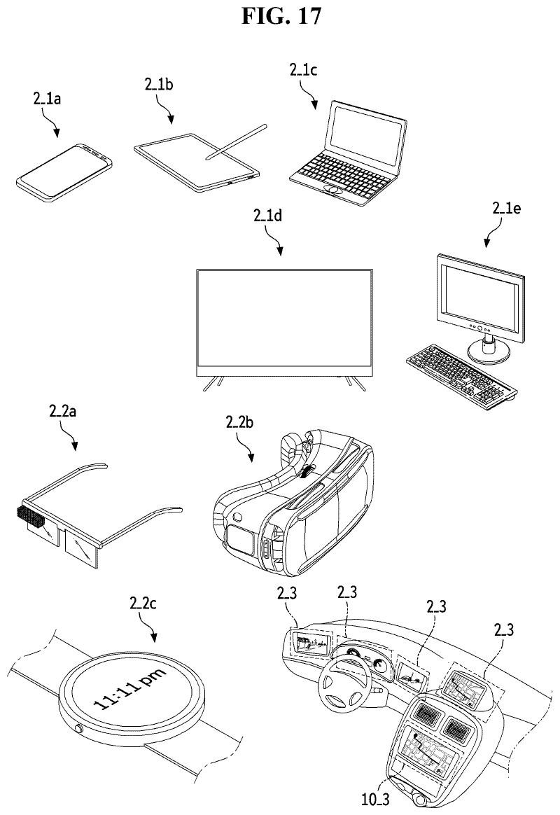

FIG. 17 illustrates schematic diagrams of electronic devices according to various embodiments.

Referring to FIG. 17, various electronic devices 2 to which the display device according to the embodiments is applied may include not only an image display electronic device such as a smart phone 2_1a, a tablet PC 2_1b, a laptop 2_1c, a TV 2_1d, and a desk monitor 2_1e, but also a wearable electronic device including a display module such as a smart glasses 2_2a, a head mounted display 2_2b, a smart watch 2_2c, and the like, and a vehicle electronic device 2_3 including a display module such as a Center Information Display (CID), a room mirror display, or the like, on a vehicle's instrument panel, center fascia, or dashboard.

Although the embodiments of the present invention have been described with reference to the attached drawings, those skilled in the art will understand that the present invention can be implemented in other specific forms without changing the technical idea or essential features of the present invention. Therefore, it should be understood that the embodiments described above are exemplary in all respects and not restrictive.

What is claimed is:

1. A display device comprising:
a substrate;
a plurality of light emitting elements disposed on the substrate; and
an encapsulation layer disposed on the plurality of light emitting elements,
wherein the encapsulation layer comprises:
a first inorganic encapsulation layer;
a monomer layer disposed on the first inorganic encapsulation layer, the monomer layer comprising a photoacid-generating monomer comprising an organic acid group represented by chemical formula 1; and
a second inorganic encapsulation layer on the monomer layer: 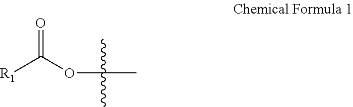
wherein in the chemical formula 1,
R₁ is H, a substituted or unsubstituted C₁₋₈ linear or branched alkyl group, a substituted or unsubstituted C₂₋₈ linear or branched alkenyl group, a substituted or unsubstituted C₃₋₈ cycloalkyl group, a substituted or unsubstituted C₃₋₈ heterocycloalkyl group, a substituted or unsubstituted C₆₋₈ aryl group, or a substituted or unsubstituted C₆₋₈ heteroaryl group.

2. The display device of claim 1, wherein when the monomer layer is exposed to light of a wavelength of 360 nm to 410 nm, the photoacid-generating monomer is cured into a photoacid-generating polymer.

3. The display device of claim 2, wherein when the monomer layer is exposed to light of a wavelength of 255 nm or less, an organic acid derivative represented by chemical formula 2 is separated from the photoacid-generating polymer: 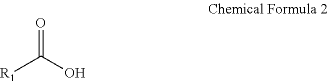
wherein in the chemical formula 2, R₁ is H, a substituted or unsubstituted C₁₋₈ linear or branched alkyl group, a substituted or unsubstituted C₂₋₈ linear or branched alkenyl group, a substituted or unsubstituted C₃₋₈ cycloalkyl group, a substituted or unsubstituted C₃₋₈ heterocycloalkyl group, a substituted or unsubstituted C₆₋₈ aryl group, or a substituted or unsubstituted C₆₋₈ heteroaryl group.

4. The display device of claim 3, wherein a volatile point of the organic acid derivative is 70° C. or lower.

5. The display device of claim 3, wherein an acid dissociation constant of the organic acid derivative is from 1.0 to 5.5.

6. The display device of claim 3, wherein the plurality of light emitting elements comprise:
a first light emitting element that emits light in a first wavelength band and is in a first light emitting area;
a second light emitting element that emits light in a second wavelength band and is in a second light emitting area; and
a third light emitting element that emits light in a third wavelength band and is in a third light emitting area.

7. The display device of claim 6, wherein the monomer layer comprises:
a first portion overlapping the first light emitting area in a thickness direction of the substrate;
a second portion overlapping the second light emitting area in the thickness direction of the substrate; and
a third portion overlapping the third light emitting area in the thickness direction of the substrate, and
an amount of the organic acid derivative of the first portion, an amount of the organic acid derivative of the second portion, and an amount of the organic acid derivative of the third portion are different.

8. The display device of claim 1, further comprising an organic encapsulation layer between the monomer layer and the second inorganic encapsulation layer.

9. The display device of claim 1, further comprising a color filter layer on the encapsulation layer.

10. A method for manufacturing a display device, the method comprising:
forming a plurality of light emitting elements on a substrate; and
forming an encapsulation layer on the plurality of light emitting elements,
wherein the forming of the encapsulation layer comprises:
forming a first inorganic encapsulation layer;
forming a monomer layer comprising a photoacid-generating monomer comprising an organic acid group represented by chemical formula 1 on the first inorganic encapsulation layer; and
forming a second inorganic encapsulation layer on the monomer layer: 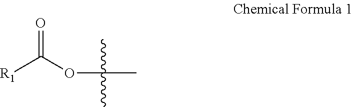
wherein in the chemical formula 1, R₁ is H, a substituted or unsubstituted C₁₋₈ linear or branched alkyl group, a substituted or unsubstituted C₂₋₈ linear or branched alkenyl group, a substituted or unsubstituted C₃₋₈ cycloalkyl group, a substituted or unsubstituted C₃₋₈ heterocycloalkyl group, a substituted or unsubstituted C₆₋₈ aryl group, or a substituted or unsubstituted C₆₋₈ heteroaryl group.

11. The method of claim 10, wherein the forming of the encapsulation layer further comprises curing the photoacid-generating monomer into a photoacid-generating polymer by irradiating the monomer layer with light of a wavelength of 360 nm to 410 nm.

12. The method of claim 11, wherein the forming of the encapsulation layer further comprises separating an organic acid derivative represented by chemical formula 2 from the photoacid-generating polymer by irradiating the monomer layer with light of a wavelength of 255 nm or less: 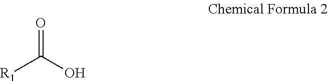
wherein in the chemical formula 2, R₁ is H, a substituted or unsubstituted C₁₋₈ linear or branched alkyl group, a substituted or unsubstituted C₂₋₈ linear or branched alkenyl group, a substituted or unsubstituted C₃₋₈ cycloalkyl group, a substituted or unsubstituted C₃₋₈ heterocycloalkyl group, a substituted or unsubstituted C₆₋₈ aryl group, or a substituted or unsubstituted C₆₋₈ heteroaryl group.

13. The method of claim 12, wherein the forming of the plurality of light emitting elements comprises:
forming a first light emitting element that emits light in a first wavelength band in a first light emitting area;
forming a second light emitting element that emits light in a second wavelength band in a second light emitting area; and
forming a third light emitting element that emits light in a third wavelength band in a third light emitting area.

14. The method of claim 13, wherein the monomer layer comprises:
a first portion overlapping the first light emitting area in a thickness direction of the substrate;
a second portion overlapping the second light emitting area in the thickness direction of the substrate; and
a third portion overlapping the third light emitting area in the thickness direction of the substrate.

15. The method of claim 14, wherein the forming of the encapsulation layer further comprises:
irradiating the first portion with light of a wavelength of 255 nm or less at a first intensity using a mask;
irradiating the second portion with light of a wavelength of 255 nm or less at a second intensity using a mask; and
irradiating the third portion with light of a wavelength of 255 nm or less at a third intensity using a mask, and
the first intensity, the second intensity, and the third intensity are different.

16. The method of claim 14, wherein the forming of the encapsulation layer further comprises:
irradiating the first portion with light of a wavelength of 255 nm or less for a first time using a mask;
irradiating the second portion with light of a wavelength of 255 nm or less for a second time using a mask; and
irradiating the third portion with light of a wavelength of 255 nm or less for a third time using a mask, and
the first time, the second time, and the third time are different.

17. The method of claim 14, wherein an amount of the organic acid derivative of the first portion, an amount of the organic acid derivative of the second portion, and an amount of the organic acid derivative of the third portion are different.

18. The method of claim 12, wherein the forming of the encapsulation layer further comprises performing heat treatment at a temperature of 70° C. or lower.

19. The method of claim 10, wherein the forming of the encapsulation layer further comprises forming an organic encapsulation layer on the monomer layer.

20. An electronic device comprising:
a display device providing an image; and
a processor transmitting a video data signal to the display device,
wherein the display device comprises:
a substrate;
a plurality of light emitting elements on the substrate; and
an encapsulation layer on the plurality of light emitting elements,
the encapsulation layer comprises:
a first inorganic encapsulation layer;
a cured monomer layer on the first inorganic encapsulation layer and comprising the cured product of a photoacid-generating monomer comprising an organic acid group represented by chemical formula 1; and
a second inorganic encapsulation layer on the monomer layer: 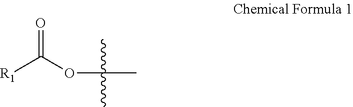
wherein in the chemical formula 1, R₁ is H, a substituted or unsubstituted C₁₋₈ linear or branched alkyl group, a substituted or unsubstituted C₂₋₈ linear or branched alkenyl group, a substituted or unsubstituted C₃₋₈ cycloalkyl group, a substituted or unsubstituted C₃₋₈ heterocycloalkyl group, a substituted or unsubstituted C₆₋₈ aryl group, or a substituted or unsubstituted C₆₋₈ heteroaryl group.
